(19) United States
(12) Patent Application Publication
(10) Pub. No.: US 2018/0108797 A1
(43) Pub. Date: Apr. 19, 2018

(54) COMPOUND LIGHT-CONCENTRATING STRUCTURE

(71) Applicant: INSTITUTE OF NUCLEAR ENERGY RESEARCH, ATOMIC ENERGY COUNCIL, EXECUTIVE YUAN, R.O.C., TAOYUAN CITY (TW)

(72) Inventors: YI-YA HUANG, TAOYUAN CITY (TW); CHUN-YI CHEN, TAOYUAN CITY (TW); HWEN-FEN HONG, TAOYUAN CITY (TW)

(21) Appl. No.: 15/295,000

(22) Filed: Oct. 17, 2016

(51) Int. Cl. H01L 31/054; H01L 31/0304; H01L 31/0232

(52) U.S. Cl. CPC H01L 31/0543; H01L 31/02327; H01L 31/0304

(57) ABSTRACT

The present invention discloses a compound light-concentrating structure, which comprises a concentrating lens and a reflective device. The reflective device is disposed below the concentrating lens with the lower end extending downwards to an extension part. The extension part further hoods a solar cell of a concentrator photovoltaic module. Thereby, after the sunlight passes through the concentrating lens, a portion of light is focused on the solar cell directly, and a portion of light is reflected by the reflective device and to the solar cell. Thereby, the photoenergy loss caused by refraction can be reduced and thus improving the performance of the concentrator photovoltaic module.

### FIELD OF THE INVENTION

The present invention relates generally to a compound light-concentrating structure, and particularly to a light-concentrating structure used in concentrator photovoltaic modules.

### BACKGROUND OF THE INVENTION

As the problems of energy exhaustion and environment pollution become serious day by day, new types of energy source are being developed aggressively worldwide. In particular, due to their property of no pollution, the energy sources extracted from the nature, such as solar power, wind power, hydroelectric power, geothermal power, and biomass power, are the emphases of development. According to researches, if the energy of the sun illuminating on the surface of the earth for one hour can be converted effectively into electrical energy, the annual global demand of electrical energy can be satisfied. Accordingly, solar cells are developed.

The first solar cell is fabricated by the Bell Lab in 1954. Thereafter, in order to improve performance, extend lifetime, and reduce manufacturing cost, the materials of cells, the structure of modules, and the packaging method are improved by proposing various solar-cell types. According to materials, solar cells can be classified into silicon solar cells (including single-crystalline silicon, polysilicon, and amorphous silicon solar cells), compound solar cells (including III-V and II-VI compound solar cells), and organic semiconductor solar cells (including organic thin-film and organic dye-sensitized solar cells). According to shapes, solar cells can be classified into bulk and thin-film types. In particular, III-V compound solar cells have the highest optoelectric conversion efficiency. Various proposals for improving the structure are provided in the related fields in the hope of overcoming current technical bottlenecks.

A concentrator photovoltaic module is formed by a light-concentrating structure and a III-V solar cell. By working with a sun tracker, the sunlight can be concentrated on the solar cell effectively and thus improving the optoelectric conversion efficiency to 35%.

The light-concentrating structure of concentrator photovoltaic module is formed by a primary optical device and a secondary optical device. The primary optical device is mainly used for concentrating and focusing the sunlight to the solar cell. The lens type can be a plano-convex lens, a biconvex lens, a paraboloidal lens, or a Fresnel lens. The secondary optical device is disposed on the surface of the solar cell. According to functions, it can be classified into concentrating, uniformizing, and angular-tolerance-increasing functions. Thereby, the designs vary; there is no regulated or generally acknowledged specification.

In the optical system formed by a plurality of optical devices according to the prior art, the primary optical device is disposed on the top of the concentrator photovoltaic module and the secondary optical device is disposed on the solar cell, meaning that the primary and secondary optical devices are discontinuous structures. Specifically, after the sunlight is concentrated by the primary optical device and focused on the secondary optical device, the secondary optical device reflects the sunlight to the solar cell. Due to the existence of the medium air between the two optical devices and the difference in refractivity between different media, energy loss will occur as the sunlight passes through different media.

In order to solve the problem of photoenergy loss caused by the light-concentrating structure, it is required to improve the light-concentrating structure according to the prior art. The present invention proposes disposing the primary and secondary optical devices continuously as well as extending the secondary optical device to the solar cell. In addition to reducing photoenergy loss by reducing the number of media passed by the sunlight, the waste of scattered light can be avoided by reflecting peripheral sunlight to the solar cell. Accordingly, the performance of the optical system can be increased and hence enhancing the efficiency of concentrator modules.

### SUMMARY

An objective of the present invention is to provide a compound light-concentrating structure, which disposes a reflective device below a concentrating lens. Thereby, the number of media passed by the sunlight incident to the concentrating photovoltaic module can be reduced, and hence lowering the loss of the sunlight.

Another objective of the present invention is to provide a compound light-concentrating structure with the reflective device extending downwards as an extension part. The extension part is further disposed on a solar cell and hoods the spot on the solar cell for reducing scattering of the sunlight and increasing the utilization efficiency of the sunlight.

In order to achieve the above objectives, the present invention discloses a compound light-concentrating structure, which comprises a concentrating lens and a reflective device. The reflective device is disposed below the concentrating lens with the lower end extending downwards as an extension part, which hoods a solar cell. Thereby, a concentrator photovoltaic module is assembled.

According to an embodiment of the present invention, the light-concentrating structure further comprises a circuit board and a solar cell. The solar cell is disposed on the circuit board. The extension part hoods the solar cell.

According to an embodiment of the present invention, the incident sunlight is concentrated by the concentrating lens and reflected by the reflective device to form a spot on the solar cell.

According to an embodiment of the present invention, the concentrating lens is a single concentrating lens or an array-type concentrating lens.

According to an embodiment of the present invention, the light-concentrating structure is an integral structure.

According to an embodiment of the present invention, the material of the reflective device is selected from the group consisting of acrylic and silica gel.

According to an embodiment of the present invention, the material of the concentrating lens is selected from the group consisting of acrylic and silica gel.

According to an embodiment of the present invention, the material of the concentrating lens corresponds to the material of the reflective device and is selected from the group consisting of acrylic and silica gel.

According to an embodiment of the present invention, the concentrating lens is a plano-convex lens or a Fresnel lens.

According to an embodiment of the present invention, the light-concentrating structure is formed by injection.

According to an embodiment of the present invention, the solar cell is a III-V compound solar cell.

### BRIEF DESCRIPTION OF THE DRAWINGS

FIG. 1 shows a structural schematic diagram according to the first embodiment of the present invention;

FIG. 2 shows an optical-path diagram according to the first embodiment of the present invention; and

FIG. 3 shows a structural schematic diagram according to the second embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

A concentrator photovoltaic module is formed by a light-concentrating structure and a solar cell. The light-concentrating structure comprises a concentrating lens and a reflective device. The sunlight is concentrate by the light-concentrating lens and focused on the reflective device. Then the reflective device reflects the concentrated sunlight to the solar cell for generating current. Thereby, the concentrating lens is called a primary optical device, while the reflective device is called a secondary device.

In the light-concentrating structure of the concentrator photovoltaic module according to the prior art, the primary optical device is disposed on the top of the photovoltaic module frame; the secondary optical device hoods the solar cell directly. Hence, there exists an air medium between the primary and the secondary optical devices. Accordingly, in the process of the incident sunlight entering the concentrator photovoltaic module, there will be three medium changes, including the sunlight entering the primary optical device from the air, the sunlight exiting the primary optical device, and the sunlight entering the secondary optical lens from the air. Owing to the difference in refractivity between different media, the energy loss is approximately 12%.

In order to solve the problem of photoenergy loss due to multiple medium changes in the process of illuminating the sunlight into the concentrator photovoltaic module, the present invention provides a light-concentrating structure, which disposes a reflective device below a concentrating lens with the lower end extending downwards to hood a solar cell. Thereby, the number of media passed by the sunlight can be reduced, and the sunlight concentrated by the light-concentrating structure can fall on the solar cell directly, and thus achieving the purpose of enhancing performance.

Based on the above guidelines, the components, properties, and the assembling method of the structure of the concentrator photovoltaic module according to the present invention will be described in the following.

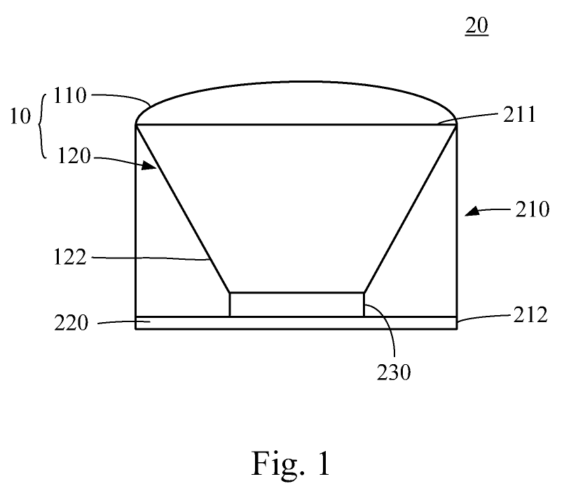

Please refer to FIG. 1, which shows a structural schematic diagram of the present invention. As shown in the figure, a concentrator photovoltaic module 20 comprises a light-concentrating structure 10, a photovoltaic module frame 210, a circuit board 220, and a solar cell 230. The solar cell 230 is disposed on the circuit board 220 and connected electrically with the circuit board 220. In addition, the circuit board 220 is disposed at a bottom 212 of the photovoltaic module frame 210. The light-concentrating structure 10 further comprises a concentrating lens 110 and a reflective device 120. The concentrating lens 110 is disposed on a top 211 of the photovoltaic module frame 210. Beside, the reflective device 120 is disposed below the concentrating lens 110 with the lower end extending downwards as an extension part 122. The extension part 122 hoods the solar cell 230 directly.

According to the above description, the concentrating lens 110 can be a plano-convex lens, a biconvex lens, a paraboloidal lens, or a Fresnel lens.

The concentrator photovoltaic module 20 uses the light-concentrating structure 10 to concentrate the sunlight and form a spot falling on the solar cell 230. Because area of the spot is small, the area of the corresponding solar cell 230 can be reduced relatively. In addition to improving the performance of solar cells, the fabrication cost can be lowered as well. Based on the above reasons, the solar cell 230 according to the present invention is a high-performance and low-cost compound solar cell. Preferably, it is a III-V compound solar cell. The III-V compound solar cell can be a single-junction or a multi junction solar cell. The shape can be, but not limited to, circular or rectangular.

The material of the light-concentrating structure 10 can be acrylic (PMMA) or silica gel, and can be formed by injection, thermal compression, casting, or molding. According to the present embodiment, the light-concentrating structure is made of silica gel by injection forming. A mold is manufactured according to the size of a light-concentrating structure. The mold further includes a top mold and a bottom mold. Next, cast silica gel into the mold. Heat the mold to reach 60° C. to 250° C. Afterwards, place still until the cast silica gel is solidified. Then, the concentrating lens and the reflective device can be formed integrally by using the top and bottom molds.

During the above fabrication process of the light-concentrating structure 10, before casting the solid material acrylic or silica gel, a transparent substrate can be first disposed between the top and bottom molds. Thereby, the concentrating lens will be formed on the transparent substrate and the reflective device will be formed below the transparent substrate, giving an integral structure.

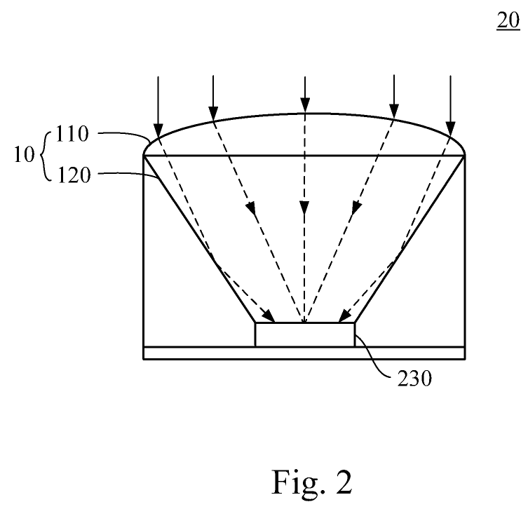

Alternatively, the light-concentrating structure 10 according to the present invention can be assembled using adhesives after the concentrating lens 110 and the reflective device 120 is fabricated. The light-concentrating performance will not differ as the fabrication method changes. Next, the light-concentrating principle of the present invention will be described. Please refer to FIG. 2, which shows an optical-path diagram according to the first embodiment of the present invention. As shown in the figure, when the sunlight is incident to the concentrating lens 110, a part of the sunlight will be concentrated to the solar cell 230 by the concentrating lens 110, while a part of the sunlight will be reflected by the reflective device 120 to the solar cell 230. The reflective device 120 extends downwards from the concentrating lens 110 and hoods the solar cell 230 directly. After the sunlight passes through the concentrating lens 110, it is focused on the solar cell 230 directly to form a spot. On the other hand, the sunlight incident from the periphery of the concentrating lens 110 is reflected to the solar cell 230 from the reflective device 120 directly without changing medium. Thereby, the photoenergy loss of the incident sunlight can be reduced, enhancing the performance of the module.

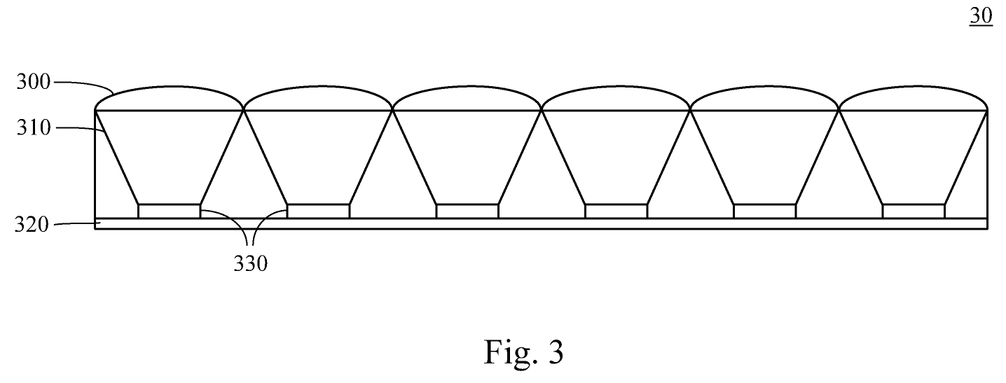

The light-concentrating structure according to the present invention can also be an array-type concentrating lens. Please refer to FIG. 3, which shows a structural schematic diagram according to the second embodiment of the present invention. As shown in the figure, a concentrator photovoltaic module 30 comprises an array-type concentrating lens 300, an array-type reflective device 310, a circuit board 320, and a plurality of solar cells 330. The plurality of solar cells 330 are disposed on the circuit board 320 and connected electrically with the circuit board 320. Besides, the array-type reflective device 310 is disposed below the array-type concentrating lens 300 and extending downwards to the plurality of solar cells 330 to hood the spots on the plurality of solar cells 330. The light-concentrating principle of the array-type concentrating lens 300 and the array-type reflective device 310 is the same as that described above in the first embodiment. Hence, the details will not be described again.

To sum up, according to the light-concentrating structure of the present invention, the reflective device is connected below the concentrating lens with the lower end extending downwards to the solar cell. Thereby, the sunlight incident from the concentrating lens can be focused directly on the solar cell and form a spot. In addition, the sunlight incident from the periphery of the concentrating lens can also be reflected to the solar cell by the reflective device. Overall, the photoenergy loss of the sunlight concentrated by the concentrating lens can be lowered by reducing changes of media. The sunlight incident from the edge of the concentrating lens can be reflected by the reflective device to avoid waste in photoenergy due to scattering of the sunlight. Thereby, the structure of concentrator photovoltaic module according to the present invention facilitates enhancing the performance of the module as well as utilization of photoenergy.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A compound light-concentrating structure, comprising:
a concentrating lens; and
a reflective device, disposed below said concentrating lens, with the lower end extending downwards as an extension part;
wherein the concentrating lens and reflective device continuously as well as extending the reflective device to a solar cell.

2. The compound light-concentrating structure of claim 1, and further comprising a circuit and a solar cell, said solar cell disposed on said circuit board, and said extension part hooding said solar cell.

3. The compound light-concentrating structure of claim 2, wherein the sunlight incident through said concentrating lens is concentrated by said concentrating lens, reflected by said reflective device, and forming a spot on said solar cell.

4. The compound light-concentrating structure of claim 2, wherein said solar cell is a III-V compound solar cell.

5. The compound light-concentrating structure of claim 1, wherein said concentrating lens is a single concentrating lens or an array-type concentrating lens.

6. The compound light-concentrating structure of claim 1, wherein said compound light-concentrating structure is formed integrally.

7. The compound light-concentrating structure of claim 1, wherein the material of said reflective device is selected from the groups consisting of acrylic and silica gel.

8. The compound light-concentrating structure of claim 1, wherein the material of said concentrating lens is selected from the groups consisting of acrylic and silica gel.

9. The compound light-concentrating structure of claim 1, wherein the material of said concentrating lens corresponds to the material of said reflective device and is selected from the group consisting of acrylic and silica gel.

10. The compound light-concentrating structure of claim 1, wherein said concentrating lens is a plano-convex lens or a Fresnel lens.

11. The compound light-concentrating structure of claim 1, wherein said compound light-concentrating structure is formed by injection, thermal compression, casting, or molding.

12. The compound light-concentrating structure of claim 1, and further forming said concentrating lens on a transparent substrate and forming said reflective lens below said transparent substrate to form an integral structure.
